(19) United States
(12) Patent Application Publication
(10) Pub. No.: US 2018/0324986 A1
(43) Pub. Date: Nov. 8, 2018

(54) Hi Performance Security Folio for Digital Mobile Devices

(71) Applicant: Tsvetana Yvanova, Woodlands Hills, CA (US)

(72) Inventor: Tsvetana Yvanova, Woodlands Hills, CA (US)

(21) Appl. No.: 15/586,219

(22) Filed: May 3, 2017

(51) Int. Cl. H05K 9/00; A45C 11/00

(52) U.S. Cl. CPC H05K 9/0083; A45C 2011/003; A45C 2011/002; A45C 11/00

(57) ABSTRACT

This hi performance invention is related to products that consumer invests in and depend for their livelihood, communication and daily existence—the digital devices. Specifically Apple products. Adding to the equation mobility as the new generations lifestyle—and it is clear that this invention is long overdue. This invention is a consumer friendly product, of distinguished aesthetics, a hi performance product with superior performance in I mechanical (A Shield) and RFID/EMF shielding qualities (E-Shield)

Apple alone has 588 million users worldwide, each one owns min of 2 devices (1.7 average), 168 Million users in the US only, A large percentage of these consumers spend time in transit—while they carry with them all their priced tools—smart phone, Mac-Air Book, MacBook-Pro, iPad . . . etc. Each consumer spends an average of $1,500-$2,000 for these smart devices. While in transit—each one of them is vulnerable to physical damage and hacking.

This dual Hi Performance Invention relates to this segment of the consumers, who need full hi performance security cases for their mobile devices (hardware/A Shield) and in digital (software—E-Shield) sense. All these qualities in one simple and sophisticated product to serve both the hardware and the software to match the value of the device it is intended to house. Final result the device extends its normal life as it is designed to do.

The impending ubiquity of RFID tags poses a potentially widespread threat to consumer privacy. Selective blocking of RFID tags for consumer privacy is paramount today. This invention fulfill to the need today's consumer of hi performance, hi shield portfolio (folio) cases for their mobile devices for their hardware and their software, that is friendly, easy to use and difficult to destroy under normal circumstances. Private information is accessibility and vulnerable to remote reading by means of new technology. The synthesis of dual protection in one simple and sophisticated product, the object of this invention. The A Shield layer—a quadruple lamination layer, and the E-Shield Silver Plated lamination layers.

Selective blocking of RFID tags for consumer privacy is a must. The impending ubiquity of RFID tags poses a potentially widespread threat to consumer privacy. The simplest RFID tag will broadcast its ID serial number—that is, its electronic product code (EPC)—to any nearby reader. The ID number. It contains not only the traditional information contained in a printed barcode (indicating manufacturer and product type), but also a unique serial number for that tag. Each consumer product or item of clothing will be uniquely identified. And yet—we offer the consumer the option to tune out—to select when to have this information open to all readers I the vicinity. Relying at that to intelligent encryption, until the device gets enclosed in the “quiet” zone. WIFI—RFID EMF complete blocking. An elegant folio with ‘faraday cage’ effect upon consumers choice

Here is where Hi Performance Security Folio steps in. The E-Shield solution—comes from a variety of specialty silver plated materials, tested for hi shielding and conductivity performance. These are integrated in the shell of the folio for ultimate shielding protection from privacy intrusion (hacking). A variety of certified and tested materials like Silver Plated Conductive Silk and Silver Plated Nylon, both high surface conductivity and the best shielding performance, Incorporates the impact resistance lamination on the interior against accidental drop, and adds to that a tactile and soft to the touch shell due to the high quality of the material in which the shell is clad.]

A-Shield (exterior) is achieved by materials that are to be cast in this organic design in a variety of formula comprising 2-3 different material—from polyurethane, polycarbonate to metal sheet, aluminum, etc (9PG06 FIG. 38. FIG. 39,) all clad In tactile, soft to the touch man made materials while preserving the protective qualities inside the folio. The materials of the product and the dimensions scale vary—but the proportions and the purpose stay identical.

The overall Design is inherent in the purpose of the Folio—hi performance and hi Shielding the contents from physical damage and unwanted privacy intrusion. The purity of intent is presented in the high aesthetics of shape and in its high performance utility. This highly aesthetic organic form—is recognized as our signature. This organically designed elegant folio case, moderated physical damage from impact of the exterior, also reducing surface wear and tear, (the A-Shield) while providing full protection form undesirable privacy intrusion by the E-Shield Performance Layers.

This dual Hi Performance invention relates to this segment of the consumers, who need full hi performance security cases for their mobile devices (hardware/A Shield) and in digital (software—E-Shield) sense. All these qualities in one simple and sophisticated product to serve both the hardware and the software to match the value of the device it is intended to house. Final result the device extends its normal life as it is designed to do.

The impending ubiquity of RFID tags poses a potentially widespread threat to consumer privacy. Selective blocking of RFID tags for consumer privacy is paramount today. This invention fulfill to the need today's consumer of hi performance, hi shield portfolio (folio) cases for their mobile devices for their hardware and their software, that is friendly, easy to use and difficult to destroy under normal circumstances. Private information is accessibility and vulnerable to remove reading by means of new technology. The synthesis of dual, even triple protection in one simple and sophisticated product, the object of this invention. The A Shield layer—a quadruple lamination layer, and the E-Shield Silver Plated lamination layers.

Selective blocking of RFID tags for consumer privacy is paramount today. The impending ubiquity of RFID tags poses a potentially widespread threat to consumer privacy. This invention relates to the mass consumer need of secure portfolio (folio) cases for mobile devices for their hardware and their software. Private information is accessibility and vulnerable to remote reading by means of new technology. The synthesis of triple protection in one simple and sophisticated product, the object of this invention.

As a tool, this security folio molded form, with its multilayered lamination system, will provide highly aesthetic and durable housing for today's consumers most valuable tools for communication and existence—iPhone, iPad and MacBook (PG01 FIG. 1-FIG. 7) as well as Its alternatives of other platforms of communication and work, that millions consumers depend on.

The aerodynamic look ((PG01, FIG. 1-FIG. 07)) that of a speed, with its nose sloped to the ground and the back elevated a bit. The organic shape If very specific when closed—distinctive roundness (PG09 FIG. 56, FIG. 57) on the sides and expressed edge on the front and on the back (PG09 FIG. 53, FIG. 54). The uniqueness is due in part to the smooth transition between the round sections and the more geometric straight edged streamlined front and back.

The interior, like the exterior is engineered to be both highly aesthetic and highly efficient in terms of mechanical and data safety. The carefully layered materials, by means of lamination process, serve different purposes. The identity protection is provided by the RFID/EMF blockers, (PG6 FIG. 38, FIG. 39) while the hi impact resistance is provided by the soft: but resilient consistency of the rubber neoprene in one of the layers allows inner protection form accidental damage (PG6, FIG. 40), while the exterior is hard enough to provide resistance outward against caving caving in on instant outside impact (PG6 FIG. 38, FIG. 39). This is possible clue to the slightly concave form of the top and bottom lids in addition to the rubber layers nestled in between, (PG09 FIG. 56, FIG. 57)

Any available products for digital devices of this nature on the marker are either very utilitarian—look like camping gear-or are clumsy and awkward looking and are not equipped to provide threefold security to its users. While computer scientists are working to create yet another way to encode privacy—we believe it simplicity—if it is not there—you cant hack it. E-SHIELD does exactly that. Makes the devices invisible to hackers.

This is the point where this invention brings to the table a simple solution—E-SHIELD—is a blend of a variety of specialty materials, integrated in the shell of the folio for ultimate shielding effect, from hacking. Part of the solution comes from the different materials we use. Conductive Safety Silk—Silver Plated Silk 65% silver, 35% silk; high surface conductivity and RF shielding, shielding performance: 40 dB over 10 MHz to 4 GHz, Stretch Conductive Silver plated Nylon: 76% Nylon, 24% elastic -Highly conductive, Silver coating is 99.9% with shielding performance: 30-50 dB, tested from 1-10 GHz, temperature range: −30 to 90° C. To name a few.

The synthesis of dual protection in one simple and sophisticated product, the object of this invention. The quadruple lamination molded shell—the [A Shield], offers shatter proof home for the most valuable electronics, and the [E-Shield] Silver Plated Hi Performance shell—offers a full protection form undesirable data intrusion.

The synthesis of the overall organic design, inherent in the purpose of the Folio—hi performance, shatter proof protection (A-Shield) is achieved by materials that are cast in this specific organic form, laminated under hi-temperature and molding three layers—from polyurethane, polycarbonate to metal sheet, aluminum, all clad in tactile, soft to the touch man made materials. Matching the hi performance shielding against unwanted privacy intrusion.

### BACKGROUD OF THIS INVENTION

This hi performance invention is related to products that consumer invests in and depend for their livelihood, communication and dally existence -the digital devices. Specifically Apple products. Adding to the equation mobility as the new generations lifestyle—and it is clear that this Invention is long overdue. This invention is a consumer friendly product, of distinguished aesthetics, a hi performance product with superior performance in I mechanical (A Shield) and RFID/EMF shielding qualities (E-Shield)

Apple alone has 588 million users worldwide, each one owns min of 2 devices (1.7 average), 168 Million users in the US only. A large percentage of these consumers spend time in transit—while they carry with them all their priced tools—smart phone, Mac-Air Book, MacBook-Pro, iPad . . . etc. Each consumer spends an average of $1,500-$2,000 for these smart devices. While in transit—each one of them is vulnerable to physical damage and hacking.

This invention relates to this consumers segment need of hi performance security cases for mobile devices in terms of mechanical (shatter proof/hardware) and in digital (hackproof/software ) sense. All these qualities in one simple and sophisticated product to serve both the hardware and the software to match the value of the device it is intended to house. Final result the device extends its normal life as it is designed to do.

In year 2017 RFID has entered the norm of daily life. RFID stands for Radio Frequency IDentification, a technology that uses tiny computer chips smaller than a grain of sand to track items at a distance. Consumer privacy concerns inhabited our daily lives along with this technology. Radio waves and electromagnetic waves are surrounding us due to our technological environment.

RFID Tags are the norm. Radio Frequency Identification (RFID) is the generic term technologies using radio waves to automatically identify people or objects. We need to be aware of the privacy implications of this technology as its use becomes more widespread. Now more than ever are these easily accessible through our r smart devices.

There is a hands-free way to steal a credit card. Adam Laurie, an RFID security expert, demonstrated a card reading Without taking the card out of the volunteer's wallet, the presentation screen showed—the person's name, account number, and expiration clearly visible. Demonstrations like that show the potential misuse of RFID technology. That is a concern.

US Passports are electronic with new microchip. The US passport has a tiny microchip embedded in it. Along with digitized pictures, security ink, all features added since 2002, the chip is an outpost in the battle to outwit tamperers. The RFID microchip in each passport contains the same personal data as it appears on the inside pages—name date of birth, place of birth, issuing office, and a digitized version of the photo. The 64 K chip can be can be read remotely. That is the concern.

RFID can be infected with a viruses. Up until now, everyone working on RFID technology has tacitly assumed that the mere act of scanning an RFID tag cannot modify back-end software, and certainly not in a malicious way. However, that vulnerabilities exist in the RFID software, an RFID tag can be (intentionally) infected with a virus and this virus can infect the backend database used by the RFID software

### DESCRIPTION OF THE INVENTION

Selective blocking of RFID tags for consumer privacy is a must. The impending ubiquity of RFID tags poses a potentially widespread threat to consumer privacy. The simplest RFID tag will broadcast its ID serial number—that is, its electronic product code (EPC)—to any nearby reader. The ID number. It contains not only the traditional information contained in a printed barcode (indicating manufacturer and product type), but also a unique serial number for that tag. Each consumer product or item of clothing will be uniquely identified. And yet—we offer the consumer the option to tune out—to select when to have this information open to all readers I the vicinity. Relying at that to intelligent encryption, until the device gets enclosed in the “quiet” zone. WIFI-RFID EMF complete blocking. An elegant folio with ‘faraday cage’ effect upon consumers choice

Here is where Security Folio fills a void. It combines simple inventions like a variety RFID blocking materials, each with their own certification, incorporates the impact resistance lamination on the interior against accidental drop, and adds to that a tactile and soft to the touch shell due to the high quality of the material t[in which the shell is clad.

This unique organic form is a molded hollow object, (PG01, PG02,PG03) seamlessly integrating top lid and bottom parts—is a form originally designed and inspired by Nature's forms—i.e. pebbles, honed to perfection by the sand and the waves. The aerodynamic look (PG09 FIG. 56, FIG. 57) that of a speed, with its nose sloped to the ground and the back elevated a bit. The organic shape if very specific when closed—distinctive roundness on the sides and expressed edge on the front and on the back. The uniqueness is due in part to the smooth transition between the round sections and the more geometric straight edged streamlined front and back.

The exterior of the design is inherent in the purpose of the Folio—it is a synthesis of triple security—interior, exterior for the hardware and digital security for the software. The purity of intent is in the synthesis of its shape and in its high utility,

The materials of this organic form are to be cast in a variety of formula—from polyurethane, polycarbonate to metal sheet, aluminum, etc (9PG06 FIG. 38, FIG. 39,), but all clad in tactile, soft to the touch man made materials while preserving the protective qualities inside the folio. The materials of the product and the dimensions scale vary—but the look and the purpose stay identical.

This organically looking elegant device moderates physical impact of its contents, reducing wear and tear, but also prevents any EMF/RFID intrusion to the consumer, thus preventing immeasurable intangible losses due to hacking or ID theft. This unique organic form offers triple protection; friendly, trustworthy, is matched only by its other qualities—tough, durable and reliable, while protecting ones privacy uncompromisingly.

Design is inherent in the purpose of the Folio. The purity of intent is presented in the shape and in its high utility. This brand recognition organic form—may be cast in different materials underneath—from polyurethane, polycarbonate to metal sheet, but all clad in soft to the touch man made materials, while preserving the qualities above.

Some surface variables in design are possible in the exterior shell only—in particular 1 surface indentations for round logo attachment, and a suitable finely crafted linear indentation for application of a zipper around the edges of the top and bottom (PG 09 FIG. 58). These are standard methods of closure that allow the possible closure of the case. Form follows function:

### DESRIPTION OF THE DRAWINGS

HI PERFORMANCE SECURITY FOLIO FOR MOBILE DIGITAL DEVICES

PAGE ONE

GENERAL EXTERIOR PERSPECTIVE VIEW OF security folio, titled SlimPRO

FIG. 1. Top lid of Security Folio body

FIG. 2 Bottom tray of security Folio

FIG. 3 Possible location/indentation for metal logo (optional)

FIG. 4 Plasticized Zipper with 2 logo pulls

FIG. 5 Retractable Steel Handle (optional)

FIG. 6 Side Steel Hook for shoulder strap (optional)

FIG. 7 Shoulder strap with metal hardware (optional)

PAGE TWO

FRONT PESPECTIVE in CLOSED & OPEN VIEW OF INVENTION

FIG. 8 Perspective View of Security Folio -CLOSED

FIG. 9 Front View/Elevation of Security Folio

FIG. 10 TOP LID interior (shape)

FIG. 11 BOTTOM Trays Interior (form)

PAGE THREE

SECURITY FOLIO PERSPECTIVE from BACK

FIG. 12 Top Lid back view

FIG. 13 Top Lid (optional) zipper indentation

FIG. 14 Back hinge location

FIG. 15 Bottom tray zipper indentation

FIG. 16 Bottom tray Interior—location for E-SHIELD lamination

PAGE FOUR

TOP VIEW OF OPEN FOLIO EXTERIOR and INTERIOR SPACE P

FIG. 17 Bottom Tray interior

FIG. 18 Bottom tray interior zipper E-Shield pocket

FIG. 19 Wateproof/Interior E-Shield Zipper For Security Pocket

FIG. 20 Bottom Tray Interior Location for logo Label

FIG. 21 TOP LID Interior with mesh pockets

FIG. 22 Top Lid Exterior location for branding identification.

FIG. 23 Bottm Tray back view Exterior

FIG. 24 Exterior Zipper plasticized dual pull, brand pull design

FIG. 25 Top Lid Exterior location for Steel Hook for Shoulder strap (optional)

FIG. 26 Bottom Lid location of Steel handle (optional)

PAGE FIVE

SECURITY FOLIO INTERIOR

FIG. 29 Interior zipper security E-Shield Enclosure

FIG. 30 Top Lid Impact—A-Shield Protection Lamination

FIG. 31 E-Shield Lamination of Double Silver Plated Hi Performance Materials

FIG. 32 Interior decorative silk lining (logo branding)

FIG. 33 Top Lid Interior silk lining (Silver Plating optional)

FIG. 34 Elastic Mesh Power Pocket A

FIG. 35 Elastic Mesh Power Pocket B

FIG. 36 Exterior Zipper/Closure Dual pull

FIG. 37 Bottom Lid ‘A-Shield’ Interior Impact Protective Laminate

PAGE SIX

SECURITY FOLIO DETIAIL CROSSESCTION OF PERFORMANCE LAYERS

FIG. 38 Bottom Tray Exterior Polyurethane Shell Clad in LeatherLike (A-Shield)

FIG. 39 Bottom -polycarbonate reinforcement underlayer(A-Shield)

FIG. 40 High Impact Rubber/Neoptrene Layer (A-Shield)

FIG. 41 E-Shield Hi Performance Layer 1

FIG. 42 E-Shield Hi Performance Layer 2

FIG. 43 Silk Lining (Brand Logo Woven Silver Plating optional)

FIG. 44 E-Shiled Pocket Performance Laminated Zipper

PAGE SEVEN

DETAILED CROSSECTION /SPECIFICTION OF PERFORMANCE SHIELDING LAMINATE

FIG. 45 Exterior Cladding—PU/leather-like. (A-Shield)

FIG. 46 Molded Shell—EVA/ molded (A Shield)

FIG. 47 Under layer of Hi Reinfoced Layer Polycarbonate (A Shield)

FIG. 48. Hi Impact Rubber/Neoprene Layer (A Shield)

FIG. 49. E-Shield Laminate Layer

FIG. 50 Interior Silk/Velvet Layer

PAGE EIGHT

DRAWING OF TOP EXTEIOR SHAPE WITH LOCATION FOR BRAND IDENTIFICATION

FIG. 51 Back/Hinge side Of Security Folio

FIG. 52 Front Section (opening) of Security Folio

FIG. 53 Location for Brand identification of Round Logo (Optional)

PAGE NINE

DRAWING OF CROOSS SECTION OF HI PERFORMANCE SECURITY FOLIO

FIG. 54 Back Of Security Folio Cross Section

FIG. 55 Front Of Security Folio Cross Section

FIG. 56 Security Folio Separation Line

FIG. 57 Top Lid Section Of Security Folio

FIG. 58 Bottom Tray of Security Folio

FIG. 59 Edge Indentation (optional)

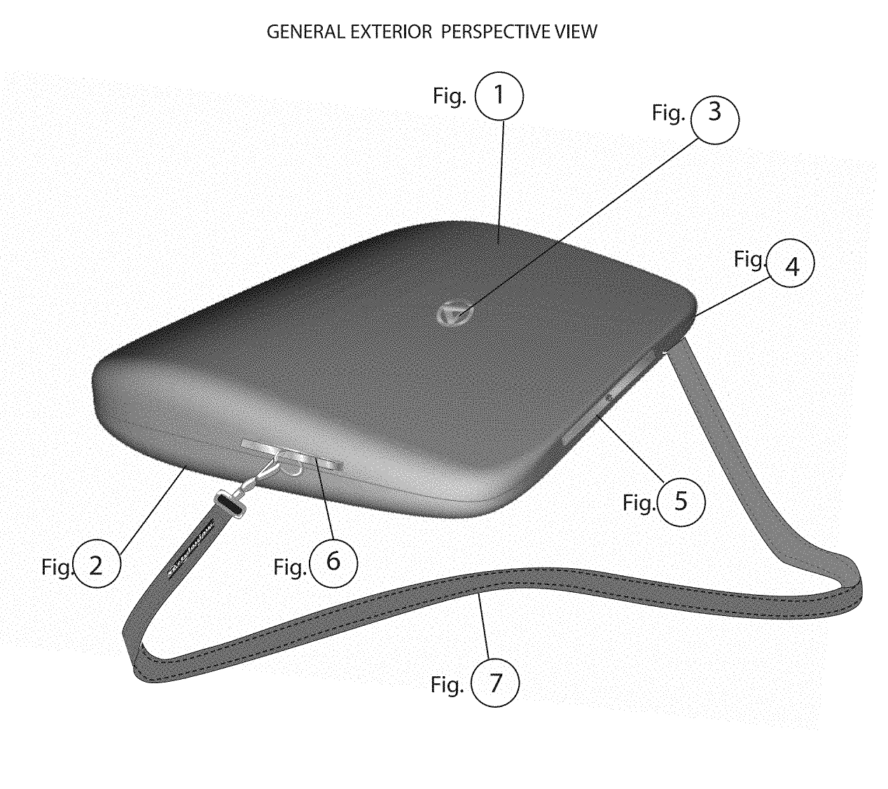

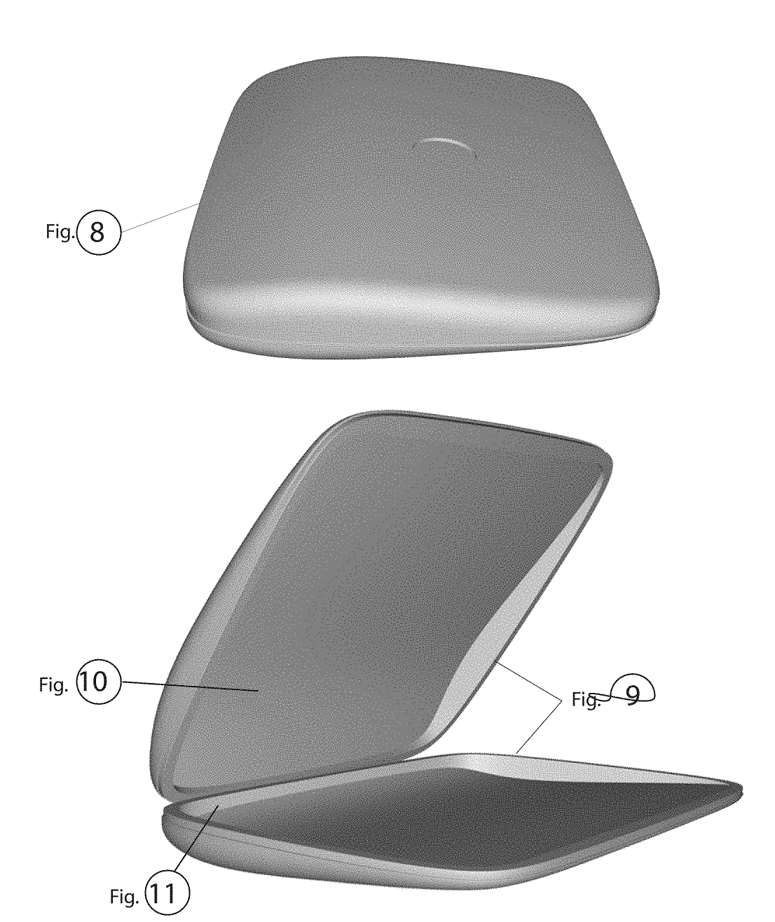

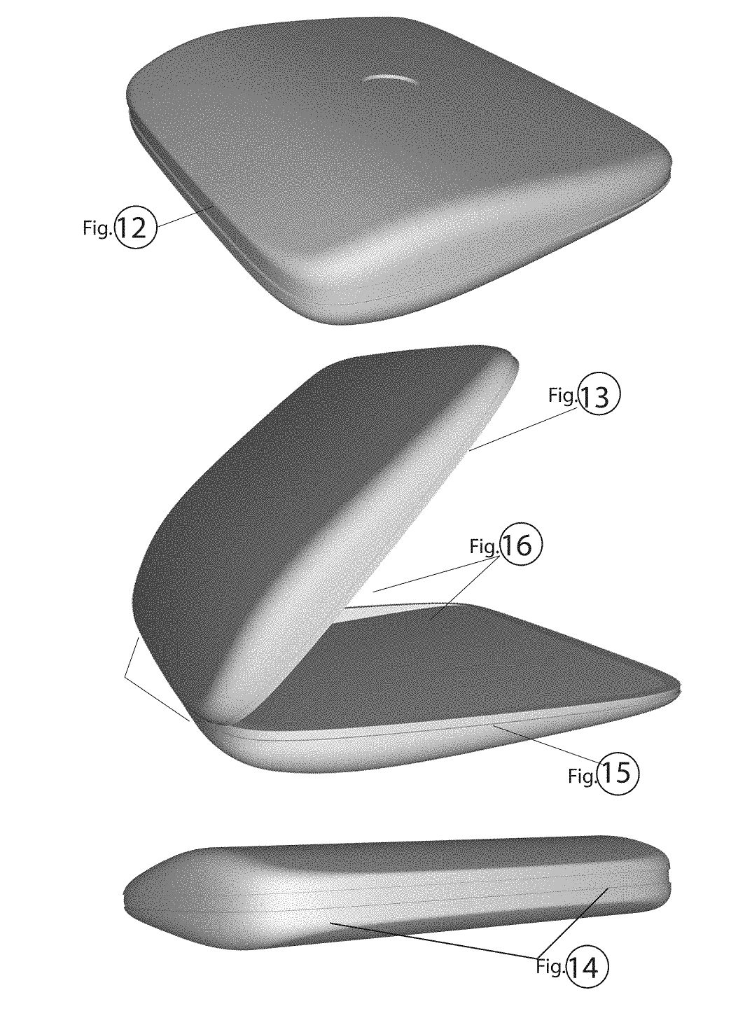

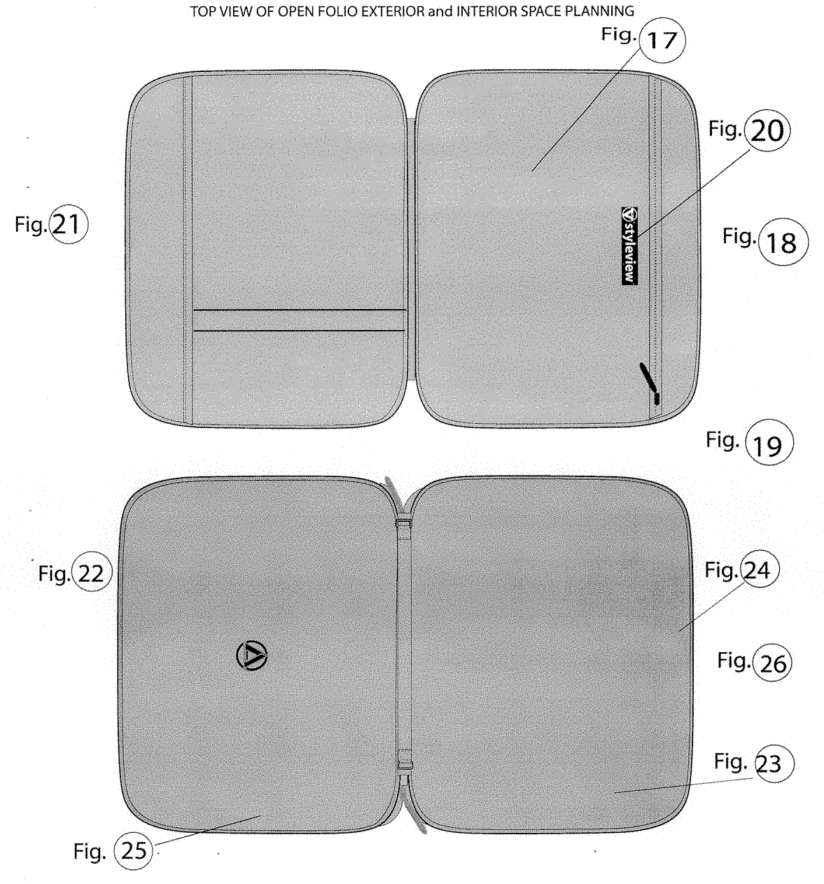

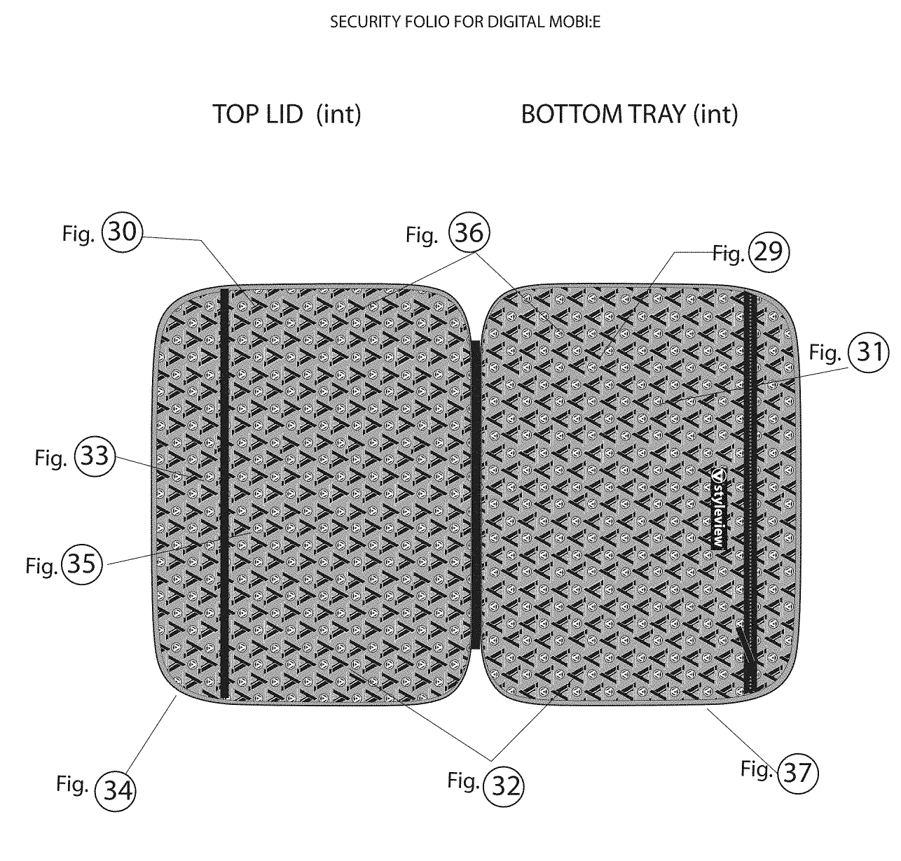

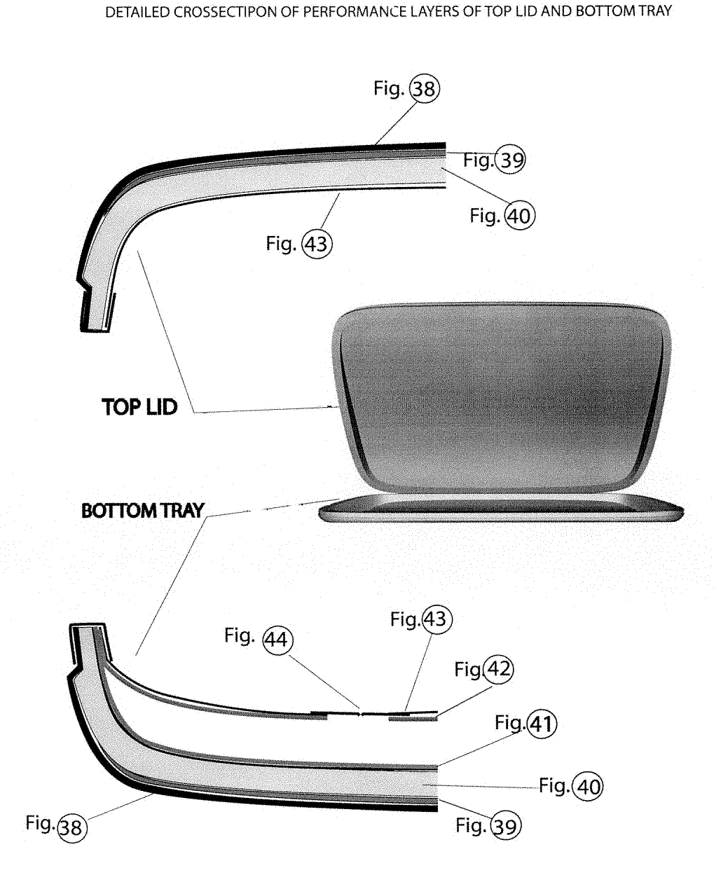

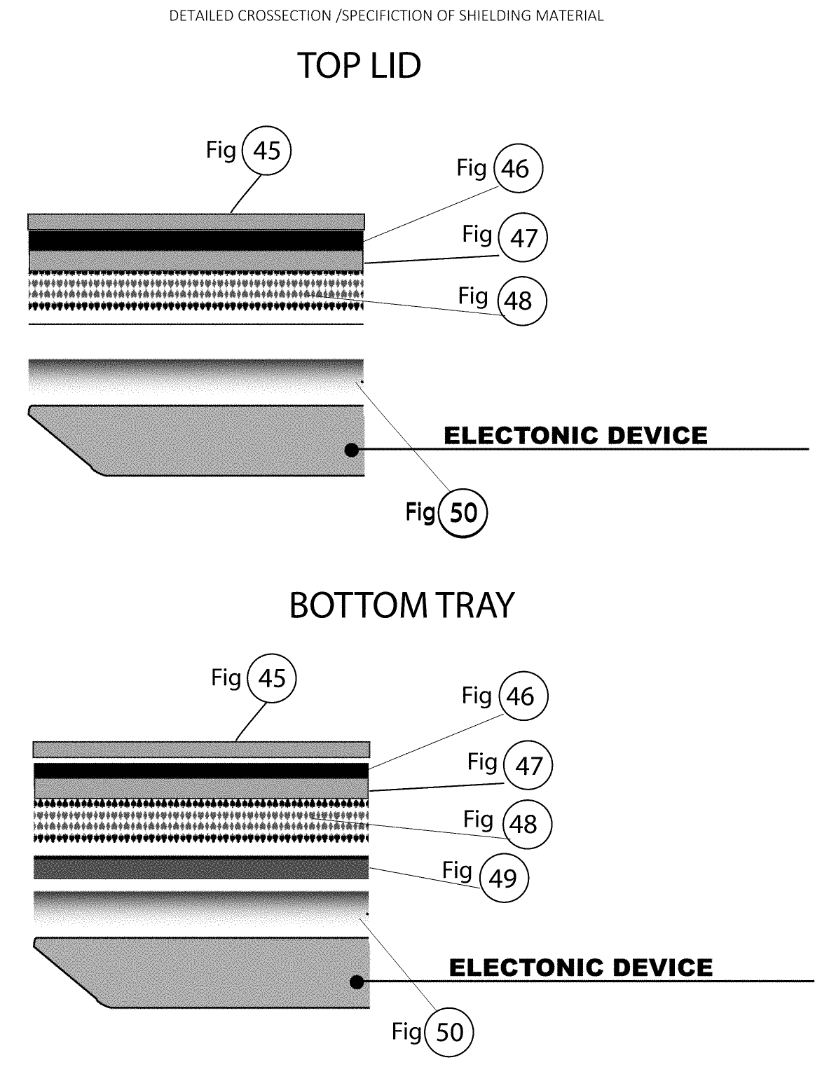

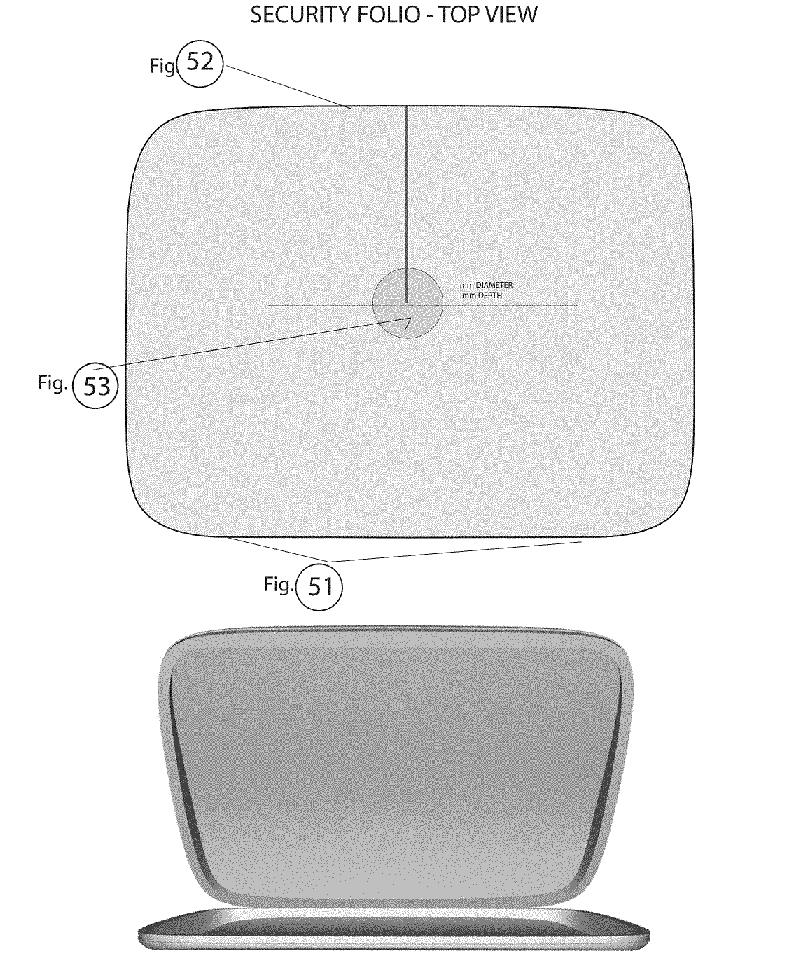

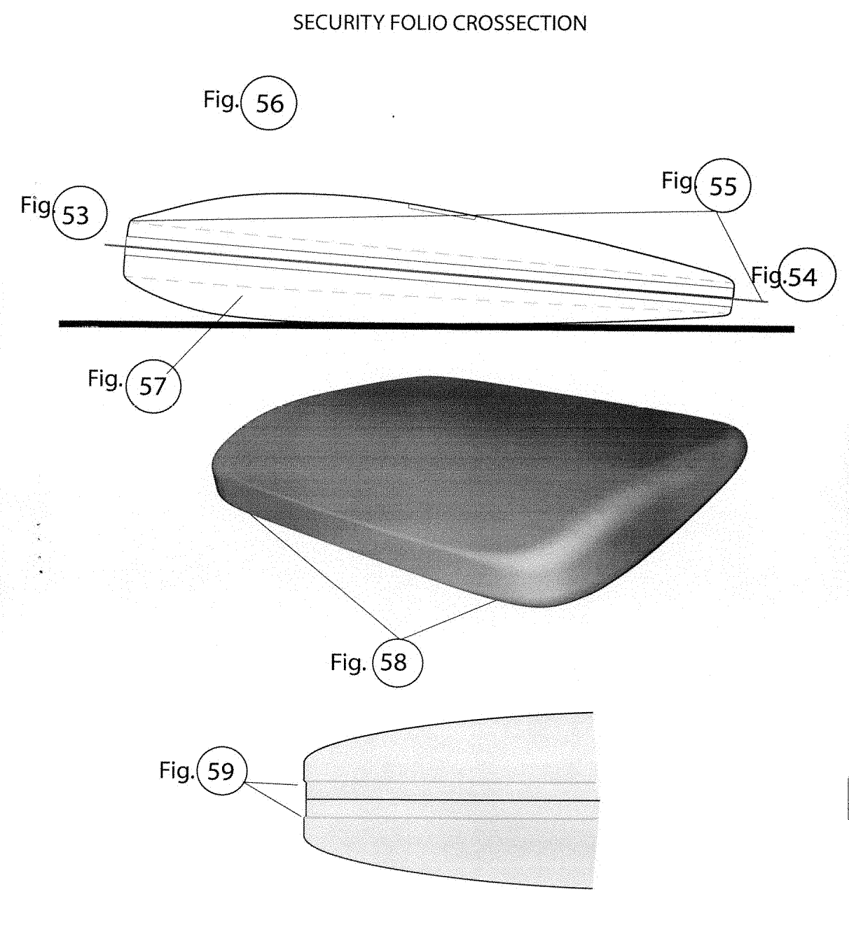

1. Durability and resilience against mechanical damage of a device is on every consumers number 1 list.] After the impending ubiquity of RFID tags, that pose a potentially widespread threat to consumer privacy, selective blocking of RFID tags is also a must. This hi performance security folio is designed to give the consumer the option to place their devices in a “quiet” zone during transit if needed. It gives them freedom. This durable, elegant folio with ‘faraday cage’ effect makes the following claims:
The A-Shield
The E-Shield
The Synthesis of the above

2. The [A-Shield] is achieved by materials that are cast in this specific organic form, laminated under hi-temperature and molding three layers—from polyurethane, polycarbonate to metal sheet, aluminum, all clad in tactile, soft to the touch man made materials. Matching the hi performance shielding against unwanted privacy intrusion.

3. The [E-Shield]—WIFI/RFID/EMF complete blocking is due to an selected variety of silver plated, materials, tested for performance qualities, integrated in the shell of the segment of the folio for ultimate privacy intrusion (hacking) shielding, A variety of Certified materials, with Copper or Silver Plated fibers are tested for Conductivity and shielding performance before applied to the product.

4. The [DUAL SHIELD] Synthesis of these two forms of shielding in one simple and sophisticated product, the object of this invention. The quadruple lamination molded shell—the [A Shield], offers shatter proof home for the most valuable electronics, and the [E-Shield] Silver Plated Hi Performance shell—offers a full protection form undesirable data intrusion and the best shielding performance. The fusion of these two in one single design is the culprit.
